(19) United States
(12) Patent Application Publication
(10) Pub. No.: US 2009/0001528 A1
(43) Pub. Date: Jan. 1, 2009

(54) Lowering resistance in a coreless package

(76) Inventors: Henning Braunisch, Chandler, AZ (US); Daniel Lu, Chandler, AZ (US)

Correspondence Address: TROP PRUNER & HU, PC, 1616 S. VOSS ROAD, SUITE 750, HOUSTON, TX, 77057-2631, US

(21) Appl. No.: 11/823,400

(22) Filed: Jun. 27, 2007

(51) Int. Cl. H01L 23/552; H01L 23/36

(52) U.S. Cl. 257/659; 257/700; 257/E23.101; 257/E23.114

(57) ABSTRACT

In one embodiment, the present invention includes a coreless substrate to provide a power net connection and a ground net connection to a semiconductor die, which is electrically coupled to the substrate, and a stiffener surrounding the semiconductor die and electrically coupled to the substrate to provide a lateral current path to the semiconductor die. Other embodiments are described and claimed.

### BACKGROUND

Semiconductor device packaging options have been proposed to provide for a so-called coreless package. Such a coreless package includes a substrate that supports one or more semiconductor die, where the substrate does not include thick metal core layers such as copper layers. Such thick core layers can provide low lateral package resistance. Such low package resistance is often needed to minimize voltage drop for low-frequency transients, i.e., controlling so-called IR drop, third droop and direct current (DC) load line. However, in coreless substrate packages, the thick core layers are not available and accordingly, low package resistance cannot be attained.

### BRIEF DESCRIPTION OF THE DRAWINGS

FIG. 1 is a cross-section view of a package in accordance with one embodiment of the present invention.

FIG. 2 is a cross-section view of a package in accordance with another embodiment of the present invention.

FIG. 3 is a cross-section view of a package in accordance with yet another embodiment of the present invention.

FIG. 4 is a cross-section view of a package in accordance with yet another embodiment of the present invention.

### DETAILED DESCRIPTION

In various embodiments, packages including a coreless substrate may be implemented without compromising low-frequency power delivery performance. In this way, improved input/output (I/O) performance may be realized, with minimized power delivery network impedance at high frequencies (i.e., first droop). Still further, reduced low-permittivity interlayer dielectric (i.e., low-k ILD) risk may be realized during assembly, enabling a reduced form factor and lower substrate costs.

More specifically, in various embodiments certain components in a coreless package such as a die-side stiffener and/or an integrated heat spreader (IHS) may be electrically connected to the coreless substrate. In this way, such components may be incorporated into the power delivery network to lower lateral package resistance. In different embodiments, these components may be electrically coupled to a ground or reference voltage net (e.g., VSS), a supply voltage net (e.g., VCC), and/or other electrical nets. Furthermore, electrical connectivity may be extended to a backside of a semiconductor die using through silicon via (TSV) interconnects.

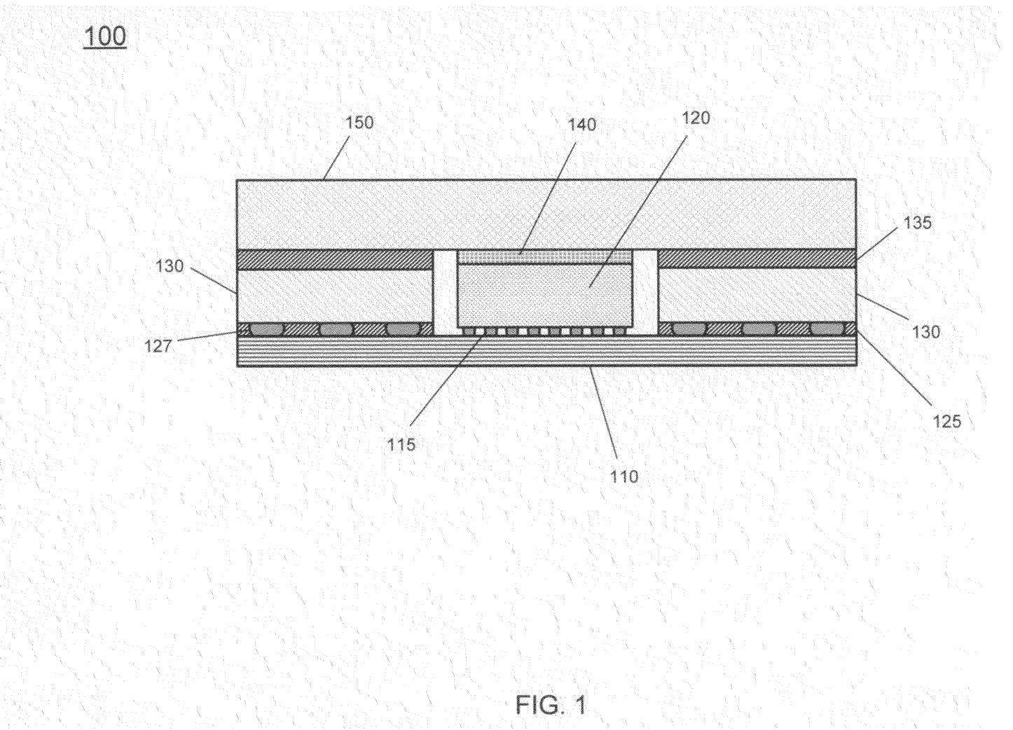

Referring now to FIG. 1, shown is a cross-section view of a package in accordance with one embodiment of the present invention. As shown in FIG. 1, package 100 may include a coreless substrate 110, which may be a multi-layer substrate formed of alternating conductive and dielectric layers and conductive vias. A semiconductor die 120 which may be a die including a processor, chipset, memory or any other semiconductor device is coupled to substrate 110 via a plurality of contacts 115, which in one embodiment may be controlled collapse chip connection (C4) bumps.

Referring still to FIG. 1, a stiffener 130, which may be formed of a conductive material such as a given metal, e.g., copper, may be electrically coupled to substrate 110 via a plurality of interconnects 127 which, in some embodiments may be solder joints, conductive adhesive, nano-metal paste (such as a copper or silver paste), or other low temperature metal-metal bonding such as gold-to-gold bonding. Furthermore, an adhesive 125 may attach stiffener 130 to substrate 110.

An integrated heat spreader (IHS) 150 may be located above stiffener 130 and die 120. Specifically, a sealant 135 and a thermal interface material (TIM) 140 may be adapted on stiffener 130 and die 120, respectively, and used to couple IHS 150 thereto.

By electrically connecting stiffener 130 to substrate 110, additional lateral current paths may be opened up through package 100. In one embodiment, stiffener 130, when formed as a single metallic body, may be connected to a ground net (e.g., VSS) of package 100.

However, in implementations such as FIG. 1 in which a single metallic body is used as a stiffener, there is a potential for excess lateral resistance for other power nets such as core power (e.g., VCC). Accordingly, in some embodiments a single conductive body stiffener may be instead replaced with a multi-layer stiffener, allowing lower lateral resistance for multiple power nets such as both a ground and supply voltage, and/or multiple supply voltages.

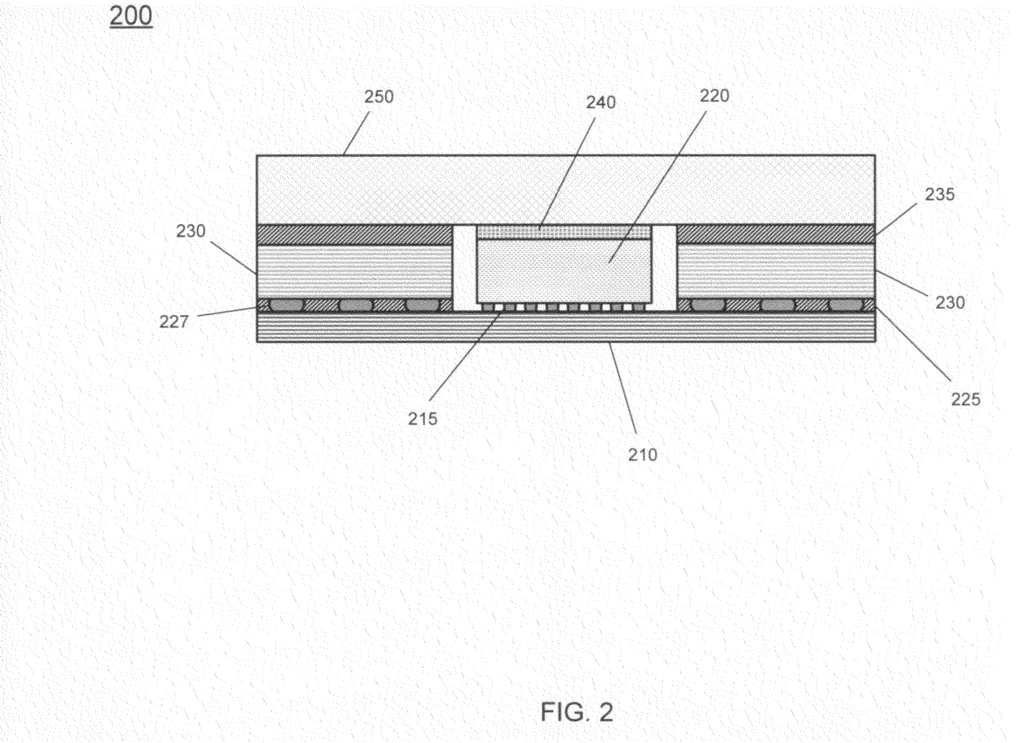

Referring now to FIG. 2, shown is a cross-section view of a package in accordance with another embodiment of the present invention. As shown in FIG. 2, stiffener 230 may be a multi-layer stiffener that allows for electrical connection of different such layers to multiple power nets. As shown in FIG. 2, package 200 may include a coreless substrate 210, such as a multi-layer substrate. A semiconductor die 220 is coupled to substrate 210 via a plurality of contacts 215, such as C4 bumps. Stiffener 230, which may be formed of multiple conductive layers, dielectric layers, and conductive vias, may be electrically coupled to substrate 210 via a plurality of interconnects 227. Some of these interconnects may couple a first layer of stiffener 230 to a power net, while other interconnects may couple a second layer to a ground net. Of course, other interconnects may electrically couple other layers to different interconnects. Furthermore, an adhesive 225 may attach stiffener 230 to substrate 210.

An IHS 250 may be located above stiffener 230 and die 220. Specifically, a sealant 235 and TIM 240 may be adapted on stiffener 230 and die 220, respectively, and used to couple IHS 250 thereto.

By electrically connecting stiffener 230 to substrate 210, additional lateral current paths may be opened up through package 200. In one embodiment, stiffener 230 may include at least two metal layers, one connected to a ground and one connected to at least one power net of package 200.

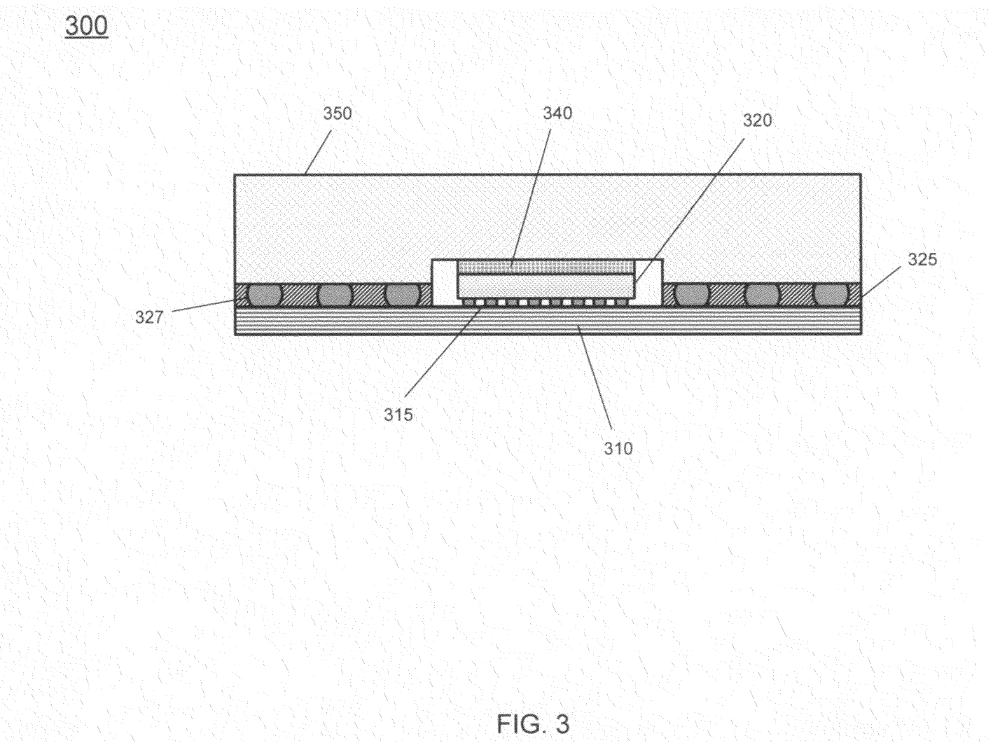

Referring now to FIG. 3, shown is a cross-section of a package in accordance with yet another embodiment of the present invention. As shown in FIG. 3, instead of a stiffener, an integrated heat spreader 350 may be electrically coupled to substrate 310. In this embodiment, IHS 350 may be grounded through this electrical connection, providing for lower lateral resistance for the ground power net. In addition, this grounding measure may have further electromagnetic interference (EMI) benefits. As further shown in FIG. 3, semiconductor die 320 may be coupled to substrate 310 via a plurality of interconnects 315. Furthermore, IHS 350 may be coupled to substrate 310 via plurality of interconnects 327 and further may be adhered thereto using a sealant 325. In various embodiments, an implementation such as that shown in FIG. 3 may be used where the semiconductor die is of a relatively thin thickness. For example, such implementations may be used with semiconductor die having a thickness of between approximately 50 micrometers and 400 micrometers. Thus in the embodiment of FIG. 3, IHS 350 both functions as a heat spreader, as well as providing electrical functionality and stiffener benefits. A TIM 340 further is adapted between die 320 and IHS 350.

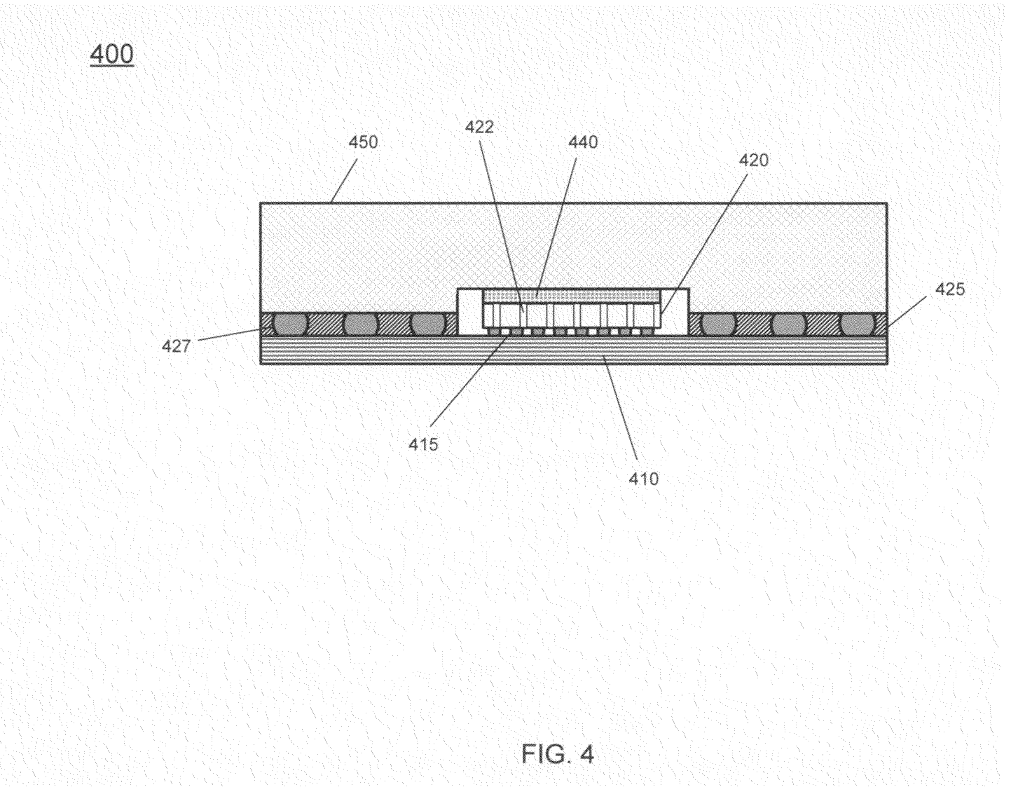

Furthermore, once electrical connectivity is established between a coreless substrate and an IHS, additional current paths may be provided through a backside of the die using TSV technology. Referring now to FIG. 4, shown is a cross section view of a package in accordance with yet another embodiment of the present invention. Specifically, a substrate 410 is coupled to a die 420 via a plurality of interconnects 415. Furthermore, an IHS 450 is coupled to substrate 410 via a plurality of interconnects 427, which may be solder joints. Furthermore, a sealant 425 may be interposed between IHS 450 and substrate 410. As shown in FIG. 4, semiconductor die 420 includes a plurality of TSVs 422 to enable electrical connections to a backside of the die. Note that in the embodiment of FIG. 4, TIM 440 may be electrically conductive, such as a solder TIM. In this way, a coreless package may be provided with multiple current paths through the IHS and die backside using TSVs.

While shown with these particular configurations in the embodiments of FIGS. 1-4, the scope of the present invention is not limited in the regard and various other configurations may be possible. For example, while shown in these figures as having flat heat spreaders (FIGS. 1 and 2) or heat spreaders having a center cavity (FIGS. 3 and 4), other embodiments may incorporate flat heat spreaders or heat spreaders having a center cavity or a center pedestal to accommodate different die thicknesses.

While the present invention has been described with respect to a limited number of embodiments, those skilled in the art will appreciate numerous modifications and variations therefrom. It is intended that the appended claims cover all such modifications and variations as fall within the true spirit and scope of this present invention.

What is claimed is:

1. An apparatus comprising:
a coreless substrate having a plurality of layers to provide a power net connection and a ground net connection to a semiconductor die;
the semiconductor die electrically coupled to the coreless substrate by a first plurality of interconnects; and
a stiffener surrounding the semiconductor die and electrically coupled to the coreless substrate by a second plurality of interconnects, wherein the stiffener is to provide a lateral current path to the semiconductor die.

2. The apparatus of claim 1, further comprising an integrated heat spreader (IHS) located above the semiconductor die and the stiffener, wherein the IHS is adapted to the semiconductor die by a thermal interface material (TIM) and to the stiffener by a sealant.

3. The apparatus of claim 1, wherein the stiffener is electrically coupled to the coreless substrate by the second plurality of interconnects comprising solder joints, a conductive adhesive, a nano paste, or metal-metal bonds.

4. The apparatus of claim 1, wherein the stiffener comprises a single conductive body to provide electrical contact with the ground net connection.

5. The apparatus of claim 1, wherein the stiffener comprises a multi-layer stiffener to provide electrical connection to at least the power net connection and the ground net connection.

6. The apparatus of claim 5, wherein a first portion of the second plurality of interconnects is to electrically couple a first layer of the stiffener with the power net connection and a second portion of the second plurality of interconnects is to electrically couple a second layer of the stiffener with the ground net connection.

7. The apparatus of claim 1, wherein the stiffener comprises a metal stiffener.

8. The apparatus of claim 1, further comprising an adhesive adapted between the coreless substrate and the stiffener.

9. An apparatus comprising:
a coreless substrate having a plurality of layers to provide a power net connection and a ground net connection to a semiconductor die;
the semiconductor die electrically coupled to the coreless substrate by a first plurality of interconnects; and
an integrated heat spreader (IHS) located above and surrounding the semiconductor die and further above the coreless substrate, wherein the IHS is adapted to the semiconductor die by a thermal interface material (TIM) and to the coreless substrate by a sealant, the IHS electrically coupled to the coreless substrate by a second plurality of interconnects, wherein the IHS is to provide a lateral current path to the semiconductor die.

10. The apparatus of claim 9, wherein the IHS is to reduce electromagnetic interference.

11. The apparatus of claim 9, wherein the semiconductor die includes a plurality of through silicon vias (TSVS) to provide a current path through a backside of the semiconductor die.

12. The apparatus of claim 9, wherein the TIM comprises an electrically conductive material.

13. The apparatus of claim 9, wherein the IHS is to electrically contact the ground net connection.
